(19) United States
(12) Patent Application Publication
(10) Pub. No.: US 2012/0168756 A1
(43) Pub. Date: Jul. 5, 2012

(54) Transistor, Method Of Manufacturing The Same, And Electronic Device Including The Transistor

(75) Inventors: Myung-kwan RYU, Yongin-si (KR); Jae-kyeong JEONG, Nam-gu (KR); Sang-yoon LEE, Seoul (KR)

(73) Assignees: INHA-INDUSTRY PARTNERSHIP INSTITUTE, Incheon (KR); SAMSUNG ELECTRONICS CO., LTD., Suwon-si (KR)

(21) Appl. No.: 13/157,773

(22) Filed: Jun. 10, 2011

(30) Foreign Application Priority Data
Dec. 31, 2010 (KR) 10-2010-0140551

(51) Int. Cl. H01L 33/16; H01L 29/786; H01L 29/04

(52) U.S. Cl. 257/59; 257/57; 257/66; 257/72; 257/E29.003; 257/E29.273; 257/E33.003; 257/E33.004

(57) ABSTRACT

Transistors, methods of manufacturing the same, and electronic devices including the transistors. The transistor may include a light blocking member which surrounds at least a portion of the channel layer. The light blocking member may be designed to block light laterally incident from a side of the transistor toward the channel layer (that is, laterally incident light). The light blocking member may be disposed in a portion of a gate insulation layer outside the channel layer. The light blocking member may be connected to a source and a drain or may be connected to a gate. The light blocking member may be separated from the source, the drain and the gate. The light blocking member may completely surround the channel layer.

### CROSS-REFERENCE TO RELATED APPLICATIONS

This application claims priority under 35 USC §119 to Korean Patent Application No. 10-2G10-0140551, filed on Dec. 31, 2G10, in the Korean Intellectual Property Office (KIPO), the disclosure of which is incorporated herein in its entirety by reference.

### BACKGROUND

1. Field

Example embodiments relate to transistors, methods of manufacturing the same, and electronic devices including the transistors.

2. Description of the Related Art

Transistors are widely used in electronic devices as switching devices or driving devices. Particularly, thin-film transistors (TFTs) may be manufactured on glass substrates or plastic substrates, and thus TFTs are very useful in flat panel display devices, such as liquid crystal display devices and organic light emitting display devices.

However, when a transistor is applied to an optical device, such as a flat panel display device, characteristics of the transistor may be changed by light. Particularly, in the case of a transistor having an oxide semiconductor channel layer, since the oxide semiconductor channel layer is sensitive to light, characteristics of the transistor may be easily changed by light.

### SUMMARY

Example embodiments are related to transistors that may reduce changes of characteristics due to light.

Example embodiments provide methods for manufacturing the transistors.

Example embodiments provide electronic devices including the transistors.

Additional aspects will be set forth in part in the description which follows and, in part, will be apparent from the description, or may be learned by practice of example embodiments.

In accordance with example embodiments, a transistor may include a gate on a substrate, a gate insulation layer on the gate, a channel layer on the gate insulation layer, a source electrode and a drain electrode respectively connected to first and second regions of the channel layer, and a light blocking member surrounding at least a portion of the channel layer, the light blocking member being configured to block laterally incident light.

In accordance with example embodiments, a transistor may include a gate disposed on a substrate, a gate insulation layer disposed to cover the gate, a channel layer disposed on the gate insulation layer, a source and a drain respectively connected to first and second regions of the channel layer, and a light blocking member, which is for blocking laterally incident light and surrounds at least a portion of the channel layer.

The light blocking member may be disposed in a portion of the gate insulation layer around the channel layer.

The light blocking member may be connected to the source and the drain.

The light blocking member may include a first member contacting the bottom surface of the source, and a second member contacting the bottom surface of the drain.

The source may contact a first end of the channel layer and extend to a portion of the gate insulation layer nearby the first end of the channel layer, the drain may contact a second end of the channel layer and extend to a portion of the gate insulation layer nearby the second end of the channel layer, and the light blocking member may include a first member contacting the bottom surface of the extended portion of the source, and a second member contacting the bottom surface of the extended portion of the drain.

The first member may include a first portion, which covers a first side surface corresponding to the first end of the channel layer, and a second portion, which extends from an end of the first portion to cover another portion of the channel layer, the second member may include a first portion, which covers a second side surface corresponding to the second end of the channel layer, and a second portion, which extends from an end of the first portion to cover another portion of the channel layer, and the second portion of the first member and the second portion of the second member may be disposed at two opposite sides of the channel layer.

The first member may include a first portion, which covers a first side surface corresponding to the first end of the channel layer, and a second portion, which extends from two opposite ends of the first portion to cover another portion of the channel layer, the second member may include a first portion, which covers a second side surface corresponding to the second end of the channel layer, and a second portion, which extends from two opposite ends of the first portion to cover another portion of the channel layer, and the second portion of the first member and the second portion of the second member may be disposed to be apart from each other.

The gate may extend between the first member and the second member.

The light blocking member may be separated from the source and the drain.

A head portion of the light blocking member may be disposed at the same level as the source and the drain.

The head portion of the light blocking member may be disposed at a different level as compared to the source and the drain.

The light blocking member may be separated from the gate.

The light blocking member may be connected to the gate.

The transistor may further include an interlayer insulation layer, which is formed on the gate insulation layer and covers the channel layer, wherein the light blocking member may be disposed in the interlayer insulation layer and the gate insulation layer.

The light blocking member may protrude above the interlayer insulation layer.

The source and the drain may be disposed on the interlayer insulation layer, and a first plug interconnecting the source and the channel layer and a second plug interconnecting the drain and the channel layer may be further disposed in the interlayer insulation layer.

If the light blocking member is disposed in the interlayer insulation layer and the gate insulation layer, the light blocking member may be separated from the source and the drain.

If the light blocking member is disposed in the interlayer insulation layer and the gate insulation layer, the light blocking member may include a first member and a second member that are separated from each other. Here, the first member may include a first portion, which covers a first side surface corresponding to a first end of the channel layer, and a second portion, which extends from an end of the first portion to cover another portion of the channel layer, the second member may include a first portion, which covers a second side surface corresponding to a second end of the channel layer, and a second portion, which extends from an end of the first portion to cover another portion of the channel layer, and the second portion of the first member and the second portion of the second member may be disposed at two opposite sides of the channel layer.

At least one of the source and the drain may extend between the first member and the second member.

The gate may extend between the first member and the second member.

The light blocking member may completely surround the channel layer. In this case, the light blocking member may contact the gate and may be separated from the source and the drain.

The gate may have a greater width than the channel layer, and the light blocking member may contact the border of the gate and surrounds the channel layer.

The gate insulation layer may be a first gate insulation layer, and a second gate insulation layer covering the light blocking member may be further disposed on the first gate insulation layer. In this case, the channel layer, the source, and the drain may be disposed on the second gate insulation layer.

The channel layer may include an oxide semiconductor.

The channel layer may include a non-oxide semiconductor.

The gate may be formed of an opaque material.

According to an aspect of example embodiments, a flat panel display device includes the transistor described above. The flat panel display device may be, for example, a liquid crystal display device or an organic light emitting display device. The transistor may be used as a switching device or a driving device.

### BRIEF DESCRIPTION OF THE DRAWINGS

These and/or other aspects will become apparent and more readily appreciated from the following description of example embodiments, taken in conjunction with the accompanying drawings of which:

FIG. 1 is a sectional view of a transistor according to example embodiments;

FIG. 2 is a plan view of the transistor shown in FIG. 1;

FIG. 3 is a sectional view taken along a line III-III′ of FIG. 2;

FIGS. 4 through 6 are plan views showing another example of the transistor shown in FIG. 1;

FIG. 7 is a sectional view of a transistor according to a comparative example;

FIG. 8 is a sectional view of a transistor according to example embodiments;

FIGS. 9 and 10 are plan views of the transistor shown in FIG. 8;

FIG. 11 is a sectional view of a transistor according to example embodiments;

FIG. 12 is a plan view of the transistor shown in FIG. 11;

FIGS. 13 and 14 are sectional views of a transistor according to example embodiments;

FIGS. 15A through 15C are diagrams showing a method of manufacturing a transistor according to example embodiments;

FIGS. 16A through 16C are diagrams showing a method of manufacturing a transistor according to example embodiments;

FIGS. 17A through 17C are diagrams showing a method of manufacturing a transistor according to example embodiments;

FIGS. 18A and 18B are diagrams showing a method of manufacturing a transistor according to example embodiments;

FIG. 19 is a sectional view showing a bottom substrate of a flat panel display including a transistor according to example embodiments;

FIG. 20 is a plan view showing the pixel region of FIG. 19;

FIG. 21 is a sectional view showing a bottom substrate of a flat panel display including a transistor according to example embodiments;

FIG. 22 is a plan view showing the pixel region shown in FIG. 21;

FIGS. 23A through 23F are diagrams showing a part of a method of manufacturing a flat panel display device including a transistor according to example embodiments;

FIGS. 24A through 24E are diagrams showing a part of a method of manufacturing a flat panel display device including a transistor according to example embodiments; and

FIG. 25 is a sectional view of a transistor according to example embodiments.

### DETAILED DESCRIPTION

Example embodiments will now be described more fully with reference to the accompanying drawings in which example embodiments are shown.

It will be understood that when an element is referred to as being “connected” or “coupled” to another element, it can be directly connected or coupled to the other element or intervening elements that may be present. In contrast, when an element is referred to as being “directly connected” or “directly coupled” to another element, there are no intervening elements present. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing example embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

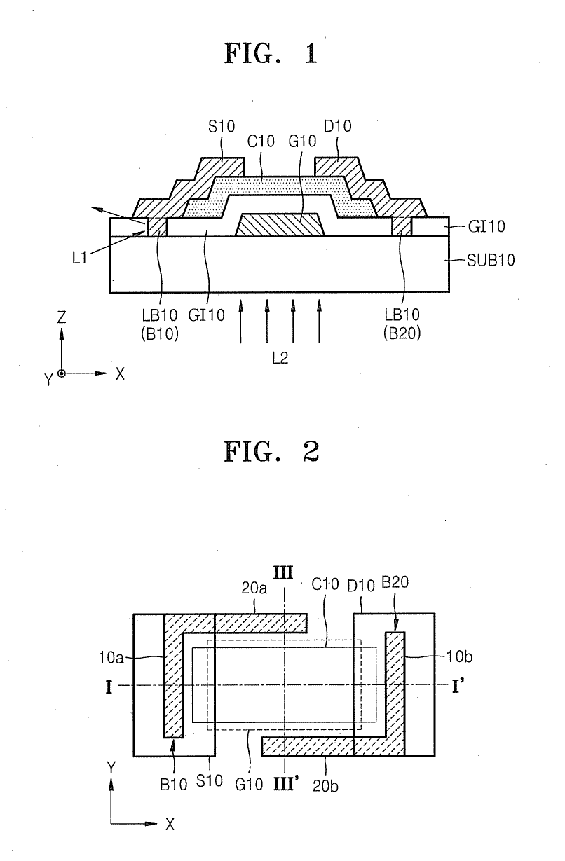

FIG. 1 is a sectional view of a transistor according to example embodiments.

Referring to FIG. 1, a gate G10 may be disposed on a substrate SUB10. The substrate SUB10 may be a glass substrate. Alternatively, the substrate SUB10 may be any of various types of substrates used in a general process for manufacturing a semiconductor device, e.g., a plastic substrate, a silicon substrate, or the like. An insulation material layer (not shown) may be formed on the substrate SUB10, and the gate G10 may be formed thereon. The insulation material layer may be a silicon oxide layer, for example. The gate G10 may be formed of a general electrode material (e.g., a metal and/or a conductive oxide). The gate G10 may be formed of an opaque material. A gate insulation layer GI10 may be formed on the substrate SUB10 to cover the gate G10. The gate insulation layer GI10 may include a silicon oxide layer, a silicon nitride layer, or any of other material layers, e.g., a high-k material layer having a dielectric constant higher than that of a silicon nitride layer. The gate insulation layer GI10 may have a single-layer structure or a multi-layer structure.

A channel layer C10 may be disposed on the gate insulation layer GI10. The channel layer C10 may be disposed above the gate G10. The x-axis direction-wise width of the channel layer C10 may be greater than the x-axis direction-wise width of the gate G10. However, it is merely an example, and the width of the channel layer C10 with respect to the gate G10 may vary. For example, the width of the gate G10 may be similar to or greater than that of the width of the channel layer C10. The channel layer C10 may be formed of an oxide semiconductor. For example, the channel layer C10 may include a ZnO-based oxide semiconductor. However, the ZnO-based semiconductor is merely an example, and any of various other oxide semiconductors may be used. If the channel layer G10 is formed of an oxide semiconductor as described above, due to excellent material properties of the oxide semiconductor including high mobility, it may be helpful for improving characteristics of the transistor. However, example embodiments are not limited thereto, and the channel layer G10 may also be formed of a non-oxide semiconductor. In this case, the channel layer G10 may be formed of amorphous silicon, polysilicon, or various (non-oxide) compound semiconductors.

A source electrode S10 and a drain electrode D10, which may respectively contact two opposite ends of the channel layer G10, may be disposed on the gate insulation layer GI10. The source electrode 810 may contact a first end of the channel layer G10 and extend onto a portion of the gate insulation layer GI10 nearby the first end of the channel layer G10. Similarly, the drain electrode D10 may contact a second end of the channel layer C10 and extend onto a portion of the gate insulation layer GI10 nearby the second end of the channel layer G10. The source electrode S10 and the drain electrode D10 may have single layer structures or multi-layer structures. The source electrode S10 and the drain electrode D10 may or may not be same material layers as the gate G10.

A light blocking member LB10, which has a structure surrounding at least a portion of the channel layer C10, may be disposed to block laterally incident light L1. The light blocking member LB10 may be disposed in the gate insulation layer GI10. The light blocking member LB10 may be disposed in a portion of the gate insulation layer GI10 outside the channel layer C10, and, when viewed from the top, the light blocking member LB10 may surround at least a portion of the channel layer C10. The light blocking member LB10 may include a first member B10 contacting the bottom surface of the source electrode S10 and a second member B20 contacting the bottom surface of the drain electrode D10. The light blocking member LB10 may be formed of a material with a characteristic of reflecting light (e.g., a metal). The light blocking member LB10 may be formed of a same material as the source electrode S10 and the drain electrode D10, and the light blocking member LB10, the source electrode S10, and the drain electrode D10 may be formed simultaneously. The light blocking member LB10 may block light that is laterally incident from a side of the transistor toward the channel layer C10, that is, the laterally incident light L1. Considering the function of the light blocking member LB10, a gap between the light blocking member LB10 and the channel layer C10 may be from about dozens nm to several μm, for example, from 0.5 μm to several μm. Meanwhile, most of light L2 incident from below the channel layer C10 may be blocked by the gate G10. If the light blocking member LB10 does not exist, light is easily incident from a side of the transistor toward the channel layer C10, and thus characteristics of the channel layer C10 may be changed. A flat panel display device may include a backlight unit (not shown) below a bottom substrate including a transistor array and a pixel electrode array, and light may be emitted by the backlight unit to the bottom substrate. Here, if a lot of light is incident to the transistor, characteristics of the transistor may be changed, and thus reliability of the flat panel display device, may be deteriorated. However, as in example embodiments, when the laterally incident light L1 that is laterally incident from a side of the transistor toward the channel layer C10 is blocked by using the light blocking member LB10, reliability of the transistor with regard to light may be improved.

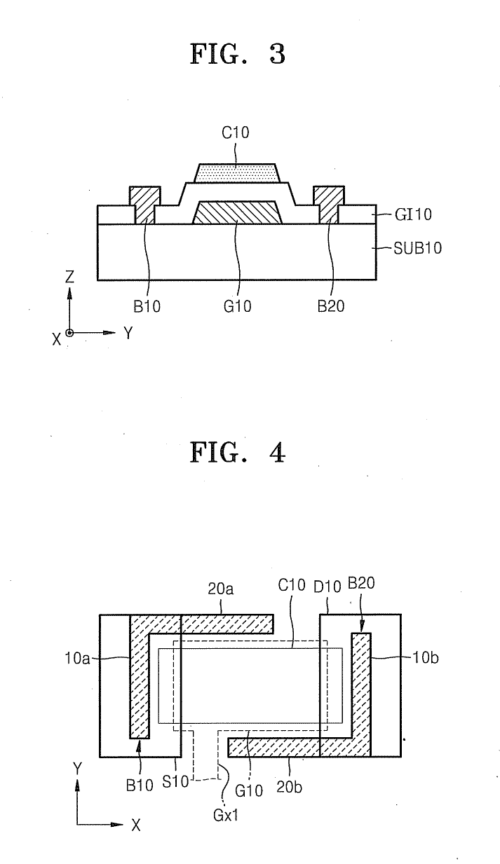

FIG. 2 is a plan view (an example) of the transistor shown in FIG. 1.

Referring to FIG. 2, the first member B10 may include a first portion 10a, which covers a first side surface corresponding to a first end of the channel layer C10, and a second portion 20a, which extends from an end of the first portion 10a to cover another portion of the channel layer C10. The second member B20 may include a first portion 10b, which covers a second side surface corresponding to a second end of the channel layer C10, and a second portion 20b, which extends from an end of the first portion 10b to cover another portion of the channel layer C10. The second portion 20a of the first member B10 and the second portion 20b of the second member B20 may be disposed at two opposite sides of the channel layer C10. The second portion 20a of the first member B10 may be spaced apart from the first portion 10b of the second member B20, whereas the second portion 20b of the second member B20 may be spaced apart from the first portion 10a of the first member B10. In example embodiments, second portion 20a of the first member B10 may be spaced apart from the first portion 10b of the second member B20 by a distance that may or may not be predetermined. Likewise, the second portion 20b of the second member B20 may be spaced apart from the first portion 10a of the first member B10 by a distance that may or may not be predetermined.

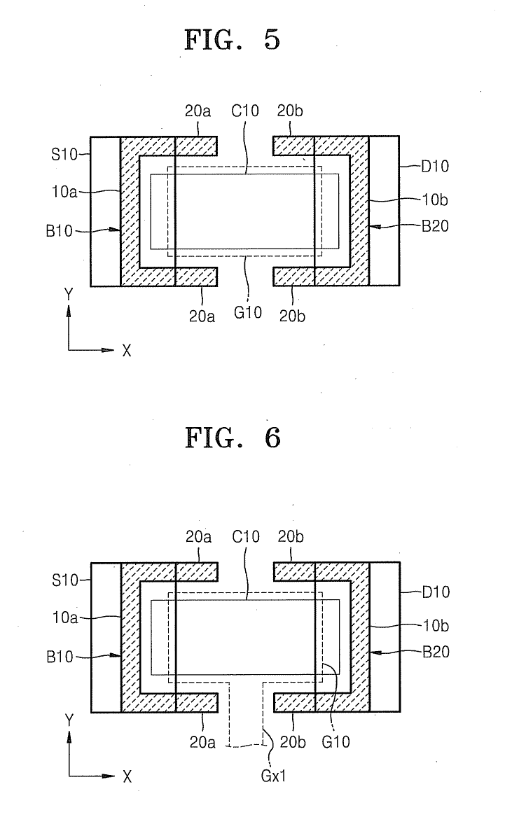

FIG.1 may be a sectional view taken along a line I-I′ of FIG. 2. On the other hand, FIG. 3 may be a sectional view taken along a line III-III′ of FIG. 2.

Referring to FIG. 3, the first member B10 and the second member B20 may protrude above the gate insulation layer GI10. Protruded portions of the first member B10 and the second member B20 may be referred to as “head portions.”

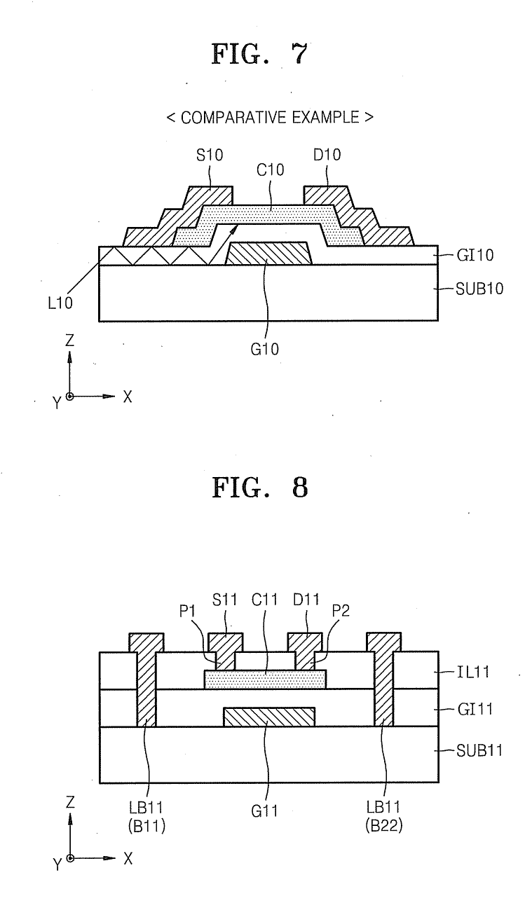

In FIG. 2, the gate G10 may have a structure extending between the first member B10 and the second member B20. An example thereof is shown in FIG. 4.

Referring to FIG. 4, the gate G10 may include an extended portion Gx1 extending between the first portion 10a of the first member B10 and the second portion 20b of the second member B20. Although not shown, the gate G10 may further include another extended portion extending between the second portion 20a of the first member B10 and the first portion 10b of the second member B20.

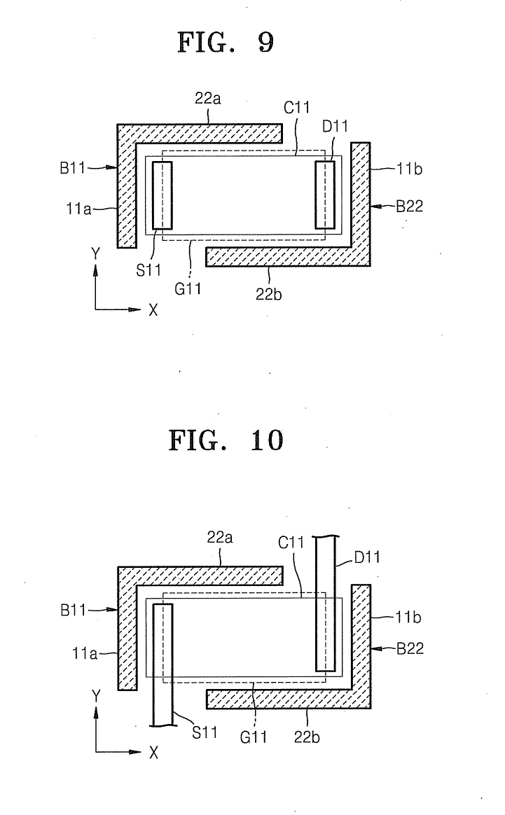

FIG. 5 is a plan view of a transistor according to example embodiments. That is, FIG. 5 is another plan view of the transistor of FIG. 1.

Referring to FIG. 5, the first member B10 may include the first portion 10a, which covers a first side surface corresponding to a first end of the channel layer C10, and the second portion 20a, which extends from both ends of the first portion 10a to cover another portion of the channel layer C10. Similarly, the second member B20 may include the first portion 10b, which covers a second side surface corresponding to a second end of the channel layer C10, and the second portion 20b, which extends from both ends of the first portion 10b to cover another portion of the channel layer C10. Here, the second portion 20a of the first member B10 and the second portion 20b of the second member B20 may be spaced apart from each other.

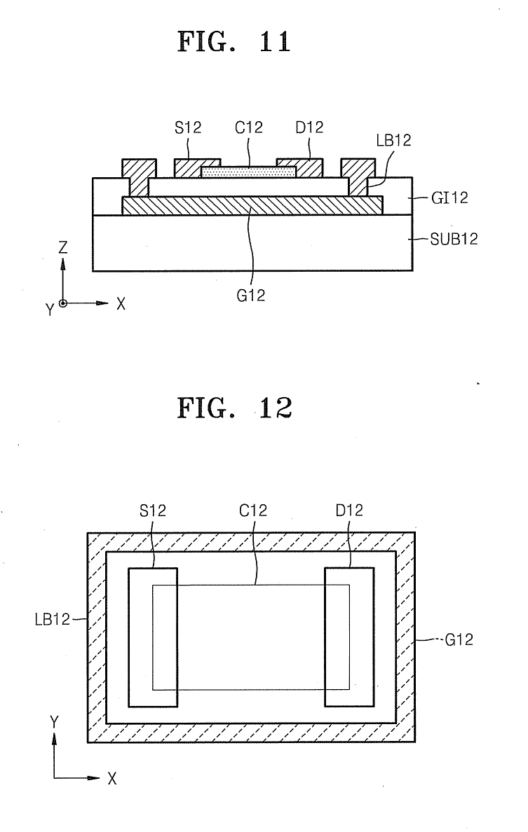

In FIG. 5, the gate G10 may have a structure extending between the first member B10 and the second member B20. An example thereof is shown in FIG. 6.

Referring to FIG. 6, the gate G10 may include an extended portion Gx1 extending between the second portion 20a of the first member B10 and the second portion 20b of the second member B20. Here, the extended portion Gx1 extends in the reverse y-axis direction, and may be located below the gate G10 in the figure. Although not shown, the gate G10 may further include another extended portion extending in the y-axis direction.

As described above, according to example embodiments, light incident from a side of the transistor toward the channel layer C10 may be blocked by arranging the light blocking member LB10 (light blocking fence, B10+B20) surrounding at least a portion of the channel layer G10, and thus changes of characteristics of the channel layer G10 and changes of characteristics of the transistor may be suppressed (minimized).

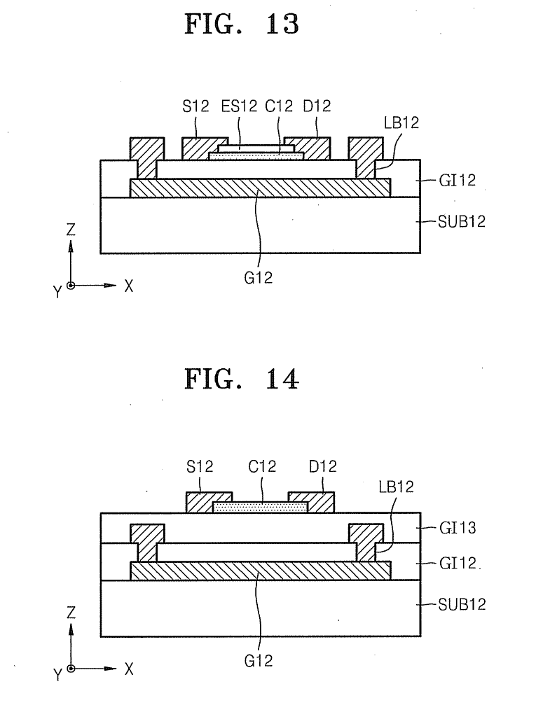

FIG. 7 is a sectional view of a transistor according to a comparative example.

The structure shown in FIG. 7 corresponds to the structure shown in FIG. 1 from which the light blocking member LB10 is removed. In the structure as shown in FIG. 7, the laterally incident light L10 may be easily incident from a side of the transistor to the channel layer C10. Particularly, as shown in FIG. 7, the laterally incident light L10 may be incident to the channel layer G10 through multiple reflections. Therefore, in the structure as shown in FIG. 7, changes of characteristics of the channel layer C10 due to light incidence may easily occur. If the channel layer G10 is a photo-sensitive oxide semiconductor layer, changes of characteristics of the channel layer G10 due to light incident may be more significant.

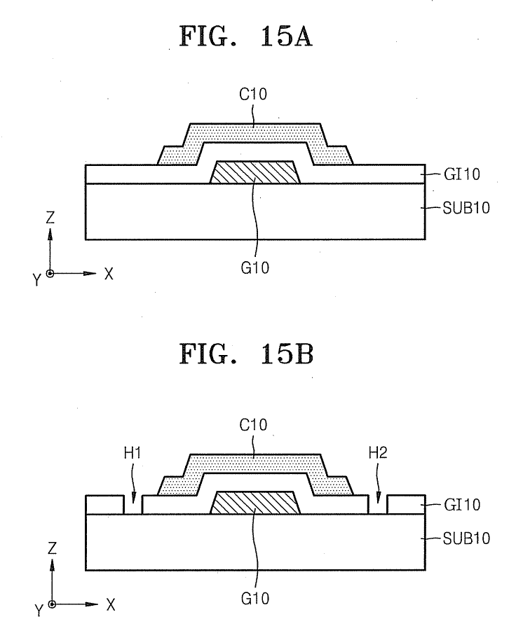

FIG. 8 is a sectional view of a transistor according to example embodiments.

Referring to FIG. 8, a gate G11 may be disposed on a substrate SUB11, and a gate insulation layer GI11 covering the gate G11 may be disposed. A channel layer C11 may be disposed on the gate insulation layer GI11. An interlayer insulation layer IL11 covering the channel layer C11 may be disposed on the gate insulation layer GI11. A source electrode S11 and a drain electrode D11 connected to the channel layer C11 may be disposed on the interlayer insulation layer IL11. A first conductive plug P1 interconnecting the source electrode S11 and the channel layer C11 and a second conductive plug P2 interconnecting the drain electrode D11 and the channel layer C11 may be disposed in the interlayer insulation layer IL11.

A light blocking member LB11 may be disposed in the gate insulation layer GI11 and the interlayer insulation layer IL11 and may protrude above the interlayer insulation layer IL11. Therefore, a protruded portion (that is, a head portion) of the light blocking member LB11 may be disposed at the same level as the source electrode S11 and the drain electrode D11. The light blocking member LB11 may include a first member B11 close to the source electrode S11 and a second member B22 close to the drain electrode D11. The light blocking member LB11 may be separated from the source electrode S11, the drain electrode D11, and the gate G11.

In FIG. 8, the interlayer insulation layer IL11 may be an etch stop layer. The interlayer insulation layer IL11 may be used as an etch stop layer during a patterning operation (etching operation) for forming the source electrode S11 and the drain electrode D11 and may protect the channel layer C11 from the etching operation.

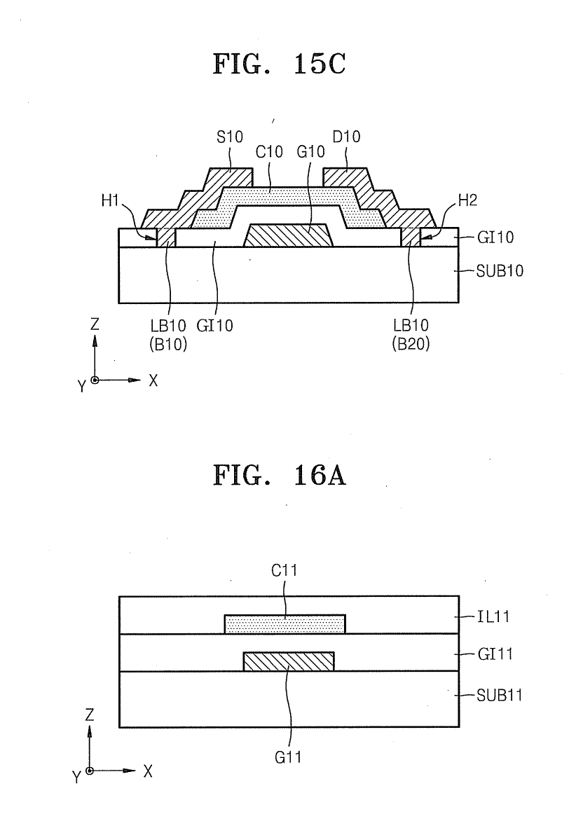

FIG. 9 is a plan view (an example) of the transistor shown in FIG. 8.

Referring to FIG. 9, the first member B11 and the second member B22 may have similar structures as the first member B10 and the second member B20 of FIG. 2, respectively. The reference numerals 11a and 22a respectively indicate a first portion 11a and a second portion 22a of the first member B11, whereas the reference numerals 11b and 22b respectively indicate a first portion 11b and a second portion 22b of the second member B22. The source electrode S11 and the drain electrode D11 may be disposed on a first end portion and a second end portion of the channel layer C11, respectively.

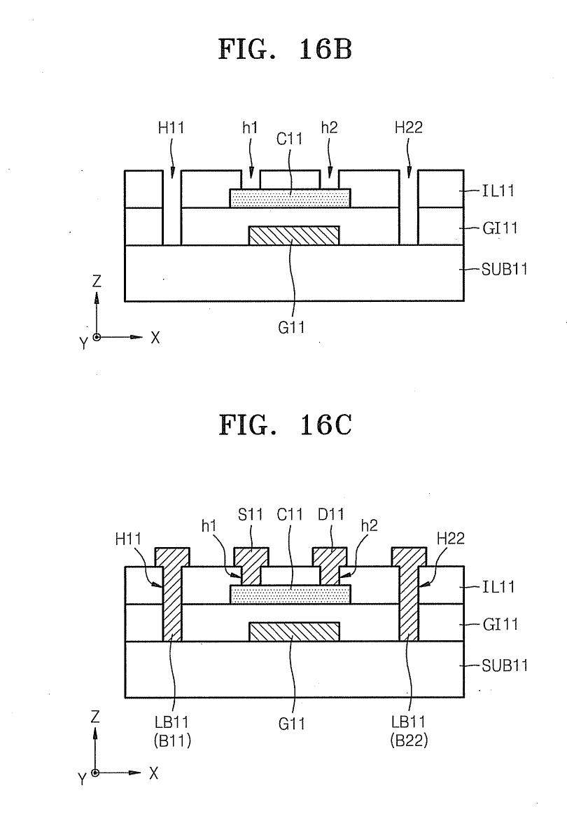

In FIG. 9, at least one of the source electrode S11 and the drain electrode D11 may extend between the first member B11 and the second member B22. An example thereof is shown in FIG. 10.

Referring to FIG. 10, the source electrode S11 may extend between the first portion 11a of the first member B11 and the second portion 22b of the second member 822. Furthermore, the drain electrode D11 may extend between the second portion 22a of the first member B11 and the first portion 11b of the second member 822.

Here, although not shown, the gate G11 shown in FIGS. 9 and 10 may extend between the first member B11 and the second member B22, similar to the gate G10 shown in FIG. 4.

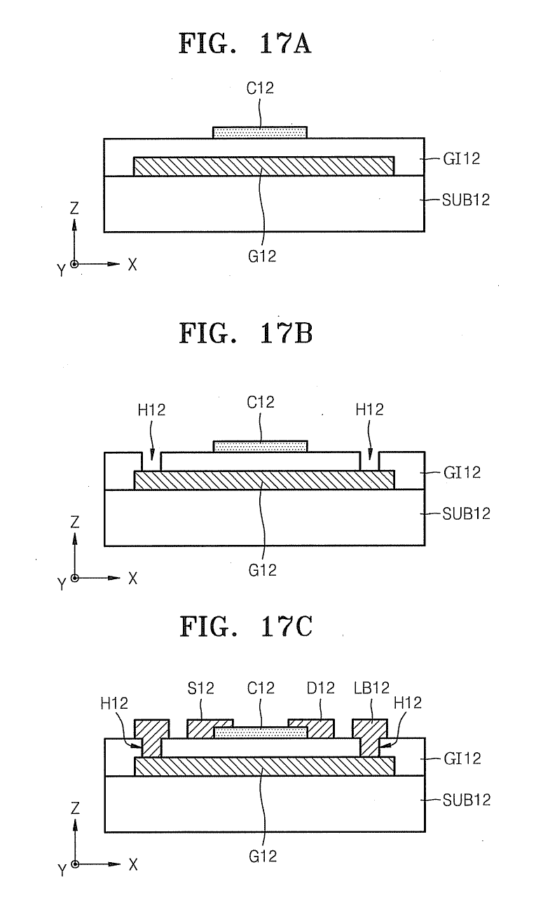

FIG. 11 is a sectional view of a transistor according to example embodiments.

Referring to FIG. 11, a gate G12 may be disposed on a substrate SUB12. Here, the gate G12 may have a greater width than the gate G10 of FIG. 1. A gate insulation layer GI12 covering the gate G12 may be disposed on the substrate SUB12. A channel layer C12 may be disposed on the gate insulation layer GI12. The width of the channel layer C12 may be smaller than that of the gate G12. A source electrode S12 and a drain electrode D12, which respectively contact two opposite ends of the channel layer C12, may be disposed on the gate insulation layer GI12. A light blocking member LB12 may be connected to the border (verge) of the gate G12 and may completely surround the channel layer C12. The light blocking member LB12 may be separated from the source electrode S12 and the drain electrode D12.

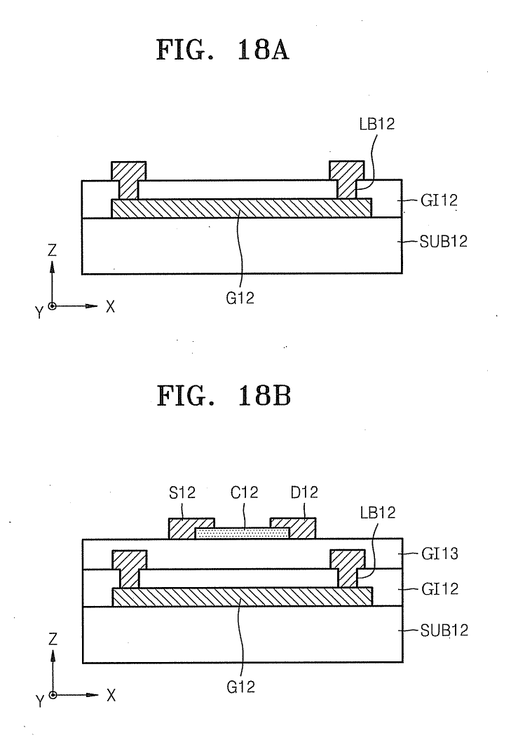

FIG. 12 is a plan view (an example) of the transistor shown in FIG. 11.

Referring to FIG. 12, the light blocking member LB12 may be disposed to be connected to the border (verge) of the gate G12 and to completely surround the channel layer C12. Although not shown, the gate G12 may further include an extended portion extending in a direction that may or may not be predetermined.

As shown in FIGS. 11 and 12, if the light blocking member LB12 is connected to the gate G12 and completely surrounds the channel layer C12, light incident from a side and below the transistor toward the channel layer C12 may be completely blocked by the light blocking member LB12 and the gate G12.

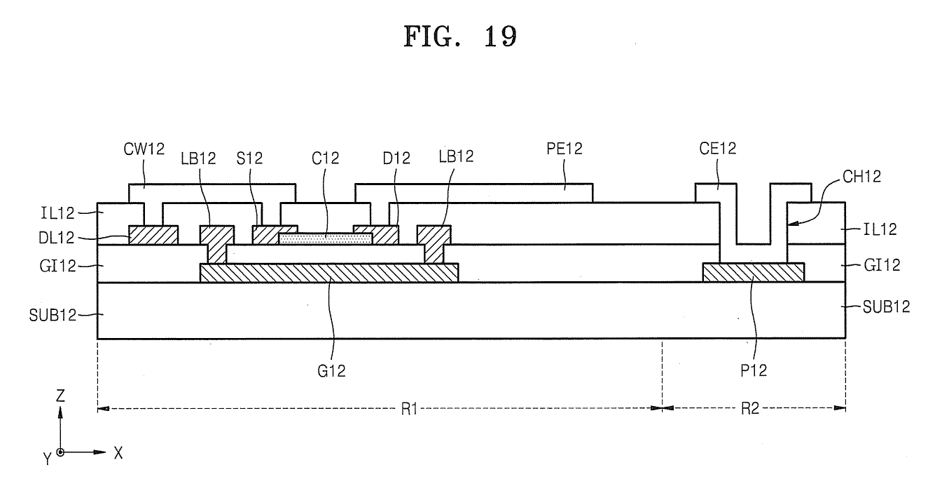

In the structure shown in FIG. 11, an etch stop layer may be further disposed on the channel layer C12. An example thereof is shown in FIG. 13.

Referring to FIG. 13, an etch stop layer ES12 may be disposed on the channel layer C12. Both ends of the channel layer C12 may not be covered by the etch stop layer ES12. If the etch stop layer ES12 is disposed on the channel layer C12 and the source electrode S12 and the drain electrode D12 are formed thereon, the channel layer C12 is not directly exposed to an etching gas during an etching operation for forming the source electrode S12 and the drain electrode D12, and thus the channel layer C12 may be protected.

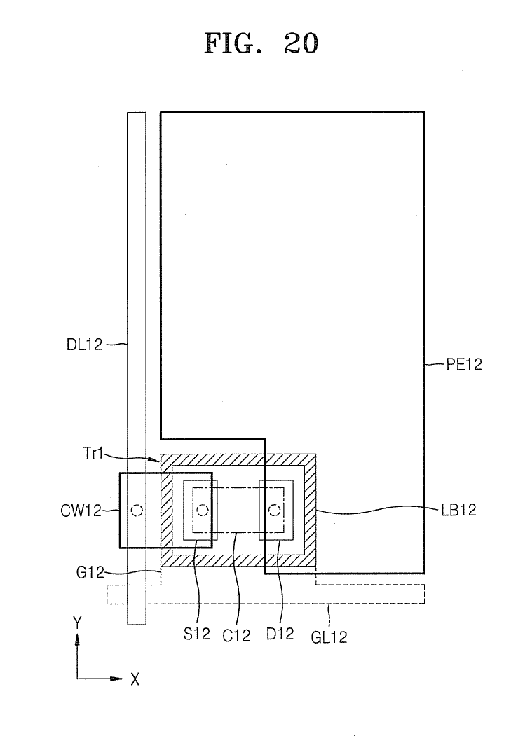

Although the protruded portion of the light blocking member LB12 (that is, the head portion) and the source/drain electrodes S12/D12 are disposed at a same level in FIGS. 11 through 13, they may also be disposed at different levels. An example thereof is shown in FIG. 14.

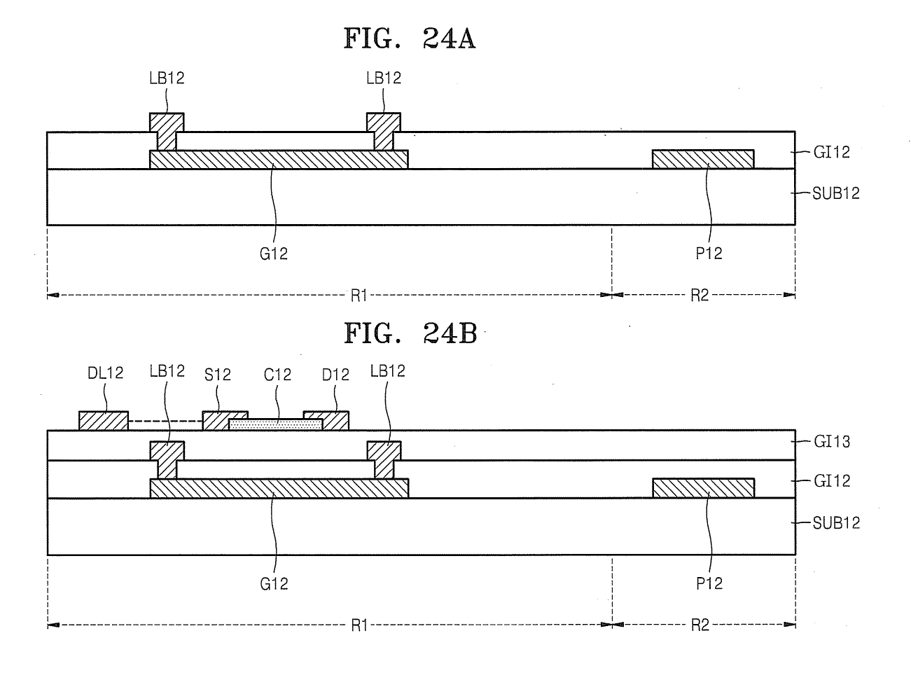

Referring to FIG. 14, a second gate insulation layer GI13 covering the light blocking member LB12 may be further disposed on the gate insulation layer GI12 (hereinafter, referred to as a first gate insulation layer). The channel layer C12, the source electrode S12, and the drain electrode D12 may be disposed on the second gate insulation layer GI13. As described above, if the source electrode S12 and the drain electrode D12 are disposed at a level different from the level at which the head portion of the light blocking member LB12 is disposed, the source electrode S12 and the drain electrode D12 may be easily connected (wired) to another component (not shown) existing at the same level as the source electrode S12 and the drain electrode D12. Detailed description thereof will be given later with reference to FIG. 21. A plan view of the structure shown in FIG. 14 may be similar to that shown in FIG: 12. Furthermore, although not shown, the etch stop layer ES12 of FIG. 13 may be applied to the structure shown in FIG. 14.

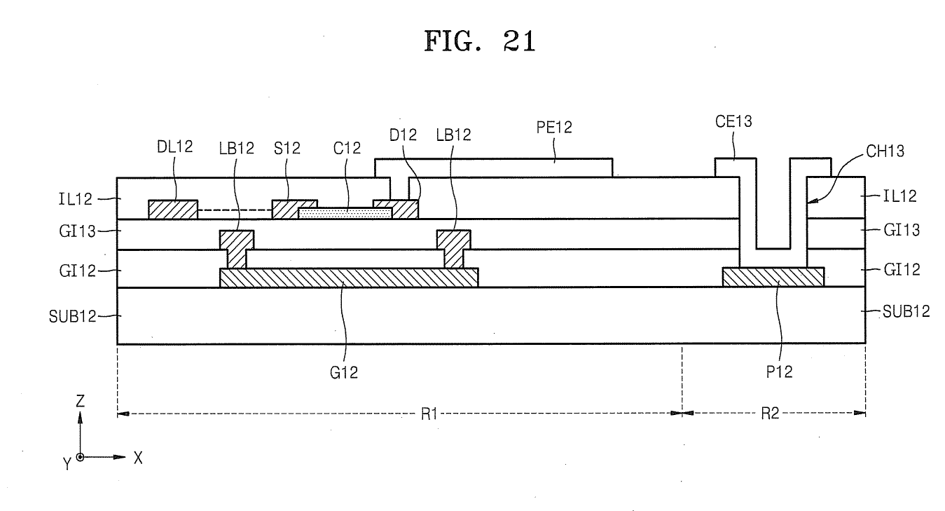

FIGS. 15A through 15C are diagrams showing a method of manufacturing a transistor according to example embodiments. The method illustrated in FIGS. 15A through 15C may be the method for manufacturing the structure shown in FIG. 1.

Referring to FIG. 15A, a gate G10 may be formed on a substrate SUB10. The substrate SUB10 may be a glass substrate or any of various other types of substrates generally used in semiconductor device manufacturing processes, e.g., a plastic substrate and/or a silicon substrate. An insulation material layer (not shown) may be formed on the substrate SUB10, and the gate G10 may be formed on the insulation material layer. The insulation material layer may be a silicon oxide layer, for example. The gate G10 may be formed of a general electrode material (e.g., a metal or a conductive oxide). The gate G10 may be an opaque component.

In example embodiments, a gate insulation layer GI10 covering the gate G10 may be formed, and a channel layer C10 may be formed on the gate insulation layer GI10. The channel layer C10 may be disposed above the gate G10 and may have a greater width than the gate G10. The channel layer C10 may be formed of either an oxide semiconductor or a non-oxide semiconductor.

Referring to FIG. 15B, holes H1 and H2 may be formed in a portion of the gate insulation layer GI10 outside the channel layer G10. The plane structure of the holes H1 and H2 may be similar to that of the first member B10 and the second member 820 shown in FIG. 2 or the first member B11 and the second member B22 shown in FIG. 5. If a transistor is used in a flat panel display device, a pad portion (not shown) may be formed in the peripheral circuit region, and the holes H1 and H2 may be formed during an operation of forming a contact hole in the pad portion. Therefore, the holes H1 and H2 may be easily formed without an additional masking operation.

Referring to FIG. 15C, a light blocking member LB10 may be formed in the holes H1 and H2 while a source electrode S10 and a drain electrode D10 are being formed. In other words, the light blocking member LB10 and the source and drain electrodes S10 and D10 may be formed simultaneously and may be formed of the same material. As described above, since the source electrode S10, the drain electrode D10, and the light blocking member LB10 may be simultaneously formed of a same material, the light blocking member LB10 may be easily formed without increasing a number of operations or complexity of operations. The plane structure of the light blocking member LB10 may be similar to that shown in FIG. 2 or FIG. 5.

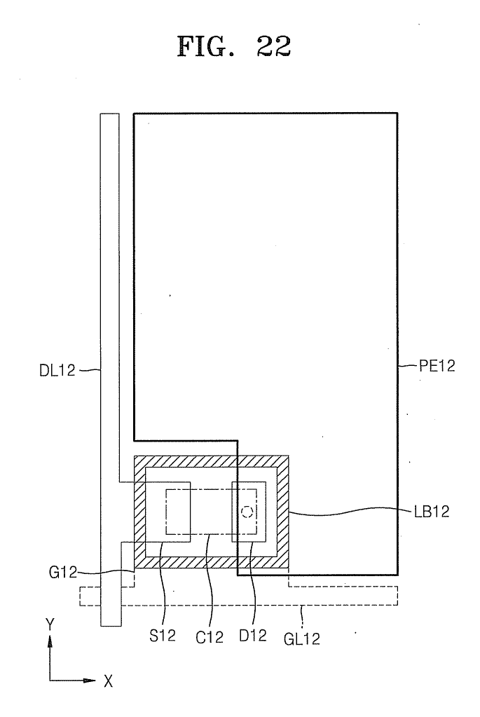

FIGS. 16A through 16C are diagrams showing a method of manufacturing a transistor according to example embodiments. The method illustrated in FIGS. 16A through 16C may be used for manufacturing the structure shown in FIG. 8.

Referring to FIG. 16A, a gate G11 may be formed on a substrate SUB11. Next, a gate insulation layer GI11 covering the gate G11 may be formed, and a channel layer C11 may be formed of the gate insulation layer GI11. The channel layer C11 may be disposed above the gate G11 and may have a greater width than the gate G11. An interlayer insulation layer IL11 covering the channel layer C11 may be formed on the gate insulation layer GI11. The interlayer insulation layer IL11 may be an etch stop layer.

Referring to FIG. 16B, holes h1 and h2 exposing the channel layer C11 may be formed by etching the interlayer insulation layer IL11, and holes H11 and H12 exposing the substrate SUB11 may formed by etching the interlayer insulation layer IL11 and the gate insulation layer GI11. The holes h1, h2, H11, and H12 may be formed during an operation of forming a contact hole in a pad portion (not shown).

Referring to FIG. 16C, a source electrode S11 and a drain electrode D11 may be formed in the holes h1 and h2 exposing the channel layer C11. At the same time, a light blocking member LB11 may be formed in the holes H11 and H12 exposing the substrate SUB11. The plane structure of the light blocking member LB11 may be similar to that shown in FIGS. 9 and 10.

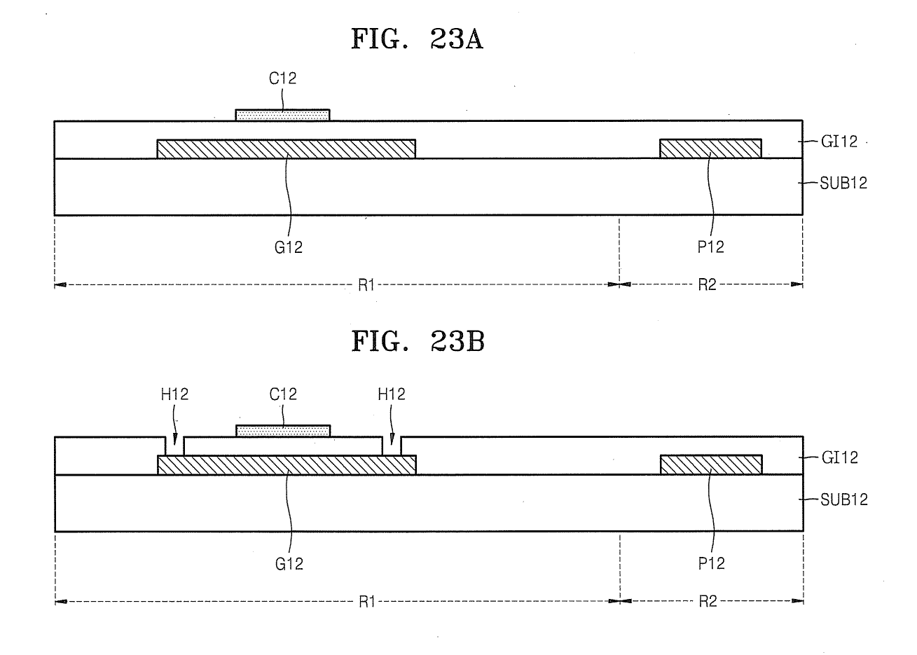

FIGS. 17A through 17C are diagrams showing a method of manufacturing a transistor according to example embodiments. The method illustrated in FIGS. 17A through 17C may be used for manufacturing the structure shown in FIG. 11.

Referring to FIG. 17A, a gate G12 may be formed on a substrate SUB12. Next, a gate insulation layer GI12 covering the gate G12 may be formed on the substrate SUB12. A channel layer C12 may be formed on the gate insulation layer GI12. The channel layer C12 may have a smaller width than the gate G12.

Referring to FIG. 17B, a hole H12 exposing a border portion of the gate G12 may be formed by etching the gate insulation layer GI12. The plane structure of the hole H12 may be similar to that of the light blocking member LB12 shown in FIG. 12, completely surrounding the channel layer C12.

Referring to FIG. 17C, a light blocking member LB12, which may be disposed in the hole H12 and may slightly protrude above the hole H12, may be formed. At the same time, a source electrode S12 and a drain electrode D12, which respectively contact two opposite ends of the channel layer C12, may be formed. The light blocking member LB12, the source electrode S12, and the drain electrode D12 may be simultaneously formed of a same material.

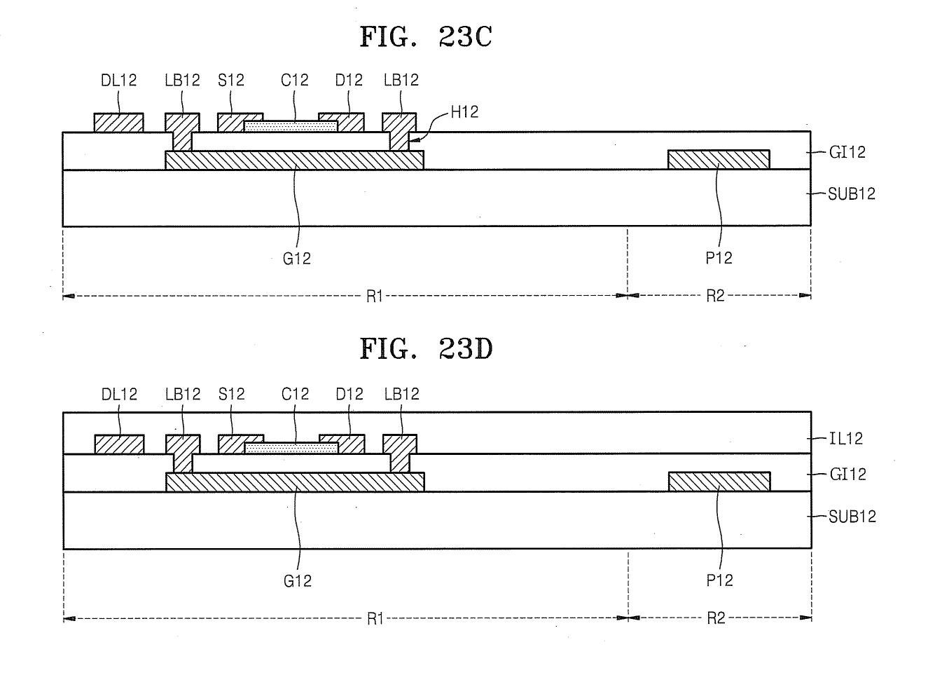

FIGS. 18A and 18B are diagrams showing a method of manufacturing a transistor according to example embodiments. The method of illustrated in FIGS. 18A and 18B may be used for manufacturing the structure shown in FIG. 14.

Referring to FIG. 18A, a gate G12 may be formed on a substrate SUB12, and a first gate insulation layer GI12 covering the gate G12 may be formed. A light blocking member LB12 may be formed in the first gate insulation layer GI12. The light blocking member LB12 may protrude above the first gate insulation layer GI12.

The plane structure of the light blocking member LB12 may be identical to that of the light blocking member LB12 shown in FIG. 12.

Referring to FIG. 18B, a second gate insulation layer GI13 covering the light blocking member LB12 may be formed on the first gate insulation layer GI12. A channel layer C12 may be formed on the second gate insulation layer GI13, and a source electrode S12 and a drain electrode D12, which contact two opposite ends of the channel layer C12, may be formed on the second gate insulation layer GI13.

As described above, according to example embodiments, highly reliable high performance transistors of which variations in characteristics due to light are suppressed (reduced) may be easily manufactured.

A transistor according to example embodiments may be applied to a flat panel display device, for example, a liquid crystal display device or an organic light emitting display device, as a switching device or a driving device, for example. As described above, a transistor according to example embodiments may have small characteristic variations due to light and excellent operation characteristics. Therefore, if a transistor according to example embodiments is applied to a flat panel display device, reliability and performance of the flat panel display device may be improved. Furthermore, a transistor according to example embodiments may be applied not only to a flat panel display device, but also to various electronic devices, for example, a memory device or a logic device, for various purposes.

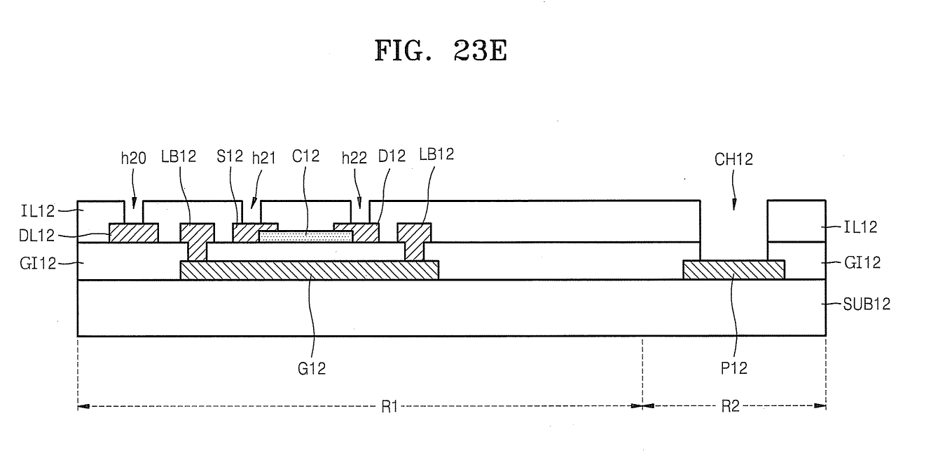

FIG. 19 is a sectional view showing a bottom substrate of a flat panel display including a transistor according to example embodiments. Here, the transistor shown in FIG. 11 is employed.

Referring to FIG. 19, a substrate SUB12 may be divided into a pixel region R1 and a peripheral region R2. A gate G12 may be disposed on the pixel region R1 of the substrate SUB12, and an electrode pad P12 may be disposed on the peripheral region R2 of the substrate SUB12. A gate insulation layer GI12 covering the gate G12 and the electrode pad P12 may be disposed on the substrate SUB12. A channel layer C12 may be disposed on a portion of the gate insulation layer GI12 on the gate G12. The width of the channel layer C12 may be smaller than that of the gate G12. A source electrode S12 and a drain electrode D12, which respectively contact two opposite ends of the channel layer C12, may be disposed on the gate insulation layer GI12. A light blocking member LB12 may be disposed in the gate insulation layer GI12, where the light blocking member LB12 may be connected to the border of the gate G12 and may completely surround the channel layer C12. The light blocking member LB12 may protrude above the gate insulation layer GI12. A data line DL12 may be disposed on the gate insulation layer GI12, apart from a side of the light blocking member LB12.

An interlayer insulation layer IL12 covering the light blocking member LB12, the channel layer C12, the source electrode S12, and the drain electrode D12 may be disposed on the gate insulation layer GI12. A contact wiring CW12 interconnecting the data line DL12 and the source electrode S12 may be disposed on the interlayer insulation layer IL12. Furthermore, a pixel electrode PE12 connected to the drain electrode D12 may be disposed on the interlayer insulation layer IL12.

A contact hole CH12 exposing the electrode pad P12 may be formed in portions of the interlayer insulation layer IL12 and the gate insulation layer GI12 in the peripheral region R2. A contact electrode CE12 contacting the electrode pad P12 may be disposed in the contact hole CH12. The contact electrode CE12, the pixel electrode PE12, and the contact wiring CW12 may be formed of a same material.

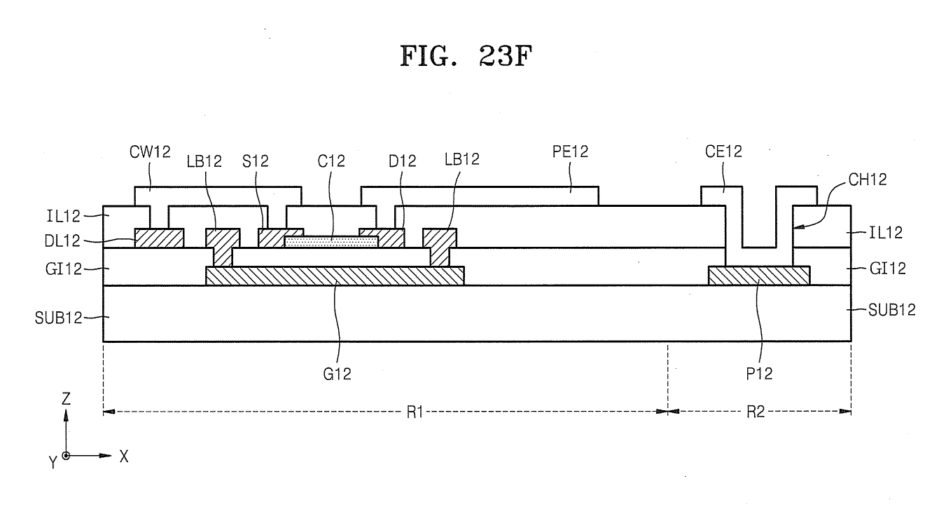

FIG. 20 is a plan view (an example) showing the pixel region R1 of FIG. 19.

Referring to FIG. 20, the data line DL12 and a gate line GL12 may be disposed to cross each other, and a transistor Tr1 may be disposed at a location where the data line DL12 and the gate line GL12 cross each other. The transistor Tr1 may include the gate G12 connected to the gate line GL12, and the channel layer C12, the source electrode S12, and the drain electrode D12 that are disposed thereon. The source electrode S12 may be connected to the data line DL12 via the contact wiring CW12, and the drain electrode D12 may be connected to the pixel electrode PE12. The light blocking member LB12 may contact the border of the gate G12 and completely surround the channel layer C12.

FIG. 21 is a sectional view showing a bottom substrate of a flat panel display including a transistor according to example embodiments. Here, the transistor shown in FIG. 14 is employed. FIG. 21 is modified from the structure of FIG. 19.

Referring to FIG. 21, a second gate insulation layer GI13 covering the light blocking member LB12 may be disposed on the gate insulation layer GI12 (hereinafter, referred to as first gate insulation layer), and the channel layer C12, the source electrode S12, and the drain electrode D12 may be disposed on the second gate insulation layer GI13. The data line DL12 may be disposed on a portion of the second gate insulation layer GI13 apart from the source electrode S12. The source electrode S12 and the data line DL12 may be connected to each other. The source electrode S12 may be a portion protruding from the data line DL12 and may be considered as a portion of the data line DL12. In FIG. 21, the light blocking member LB12 is disposed at a lower level as compared to the source electrode S12 and the drain electrode D12, and thus the source electrode S12 and the data line DL12 may be easily connected to each other. An interlayer insulation layer IL12 covering the channel layer C12, the source electrode S12, and the drain electrode D12 may be disposed on the second gate insulation layer GI13. A pixel electrode PE12 connected to the drain electrode D12 may be disposed on the interlayer insulation layer IL12.

Meanwhile, in the peripheral region R2, a contact hole CH13 exposing the electrode pad P12 may be formed in portions of the interlayer insulation layer IL12, the second gate insulation layer GI13, and the first gate insulation layer GI12. A contact electrode CE13 connected to the electrode pad P12 may be disposed in the contact hole CH13. The contact electrode CE13 may be formed of a same material as the pixel electrode PE12.

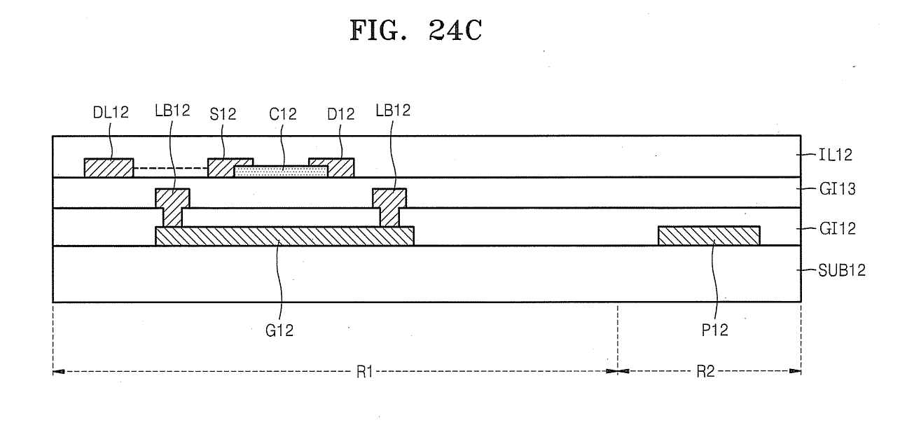

FIG. 22 is a plan view (an example) showing the pixel region R1 shown in FIG. 21.

The structure shown in FIG. 22 is similar to that shown in FIG. 20. However, in FIG. 22, the source electrode S12 is directly connected to the data line DL12. In other words, the source electrode S12 may be a protruded portion of the data line DL12. The direct connection between the source electrode S12 and the data line DL12 may be possible because of the fact that the light blocking member LB12 is formed at a lower level as compared to the source electrode S12 and the drain electrode D12. The remaining structure other than the direct connection of the source electrode S12 to the data line DL12 is identical to the structure shown in FIG. 20, and thus detailed description thereof will be omitted.

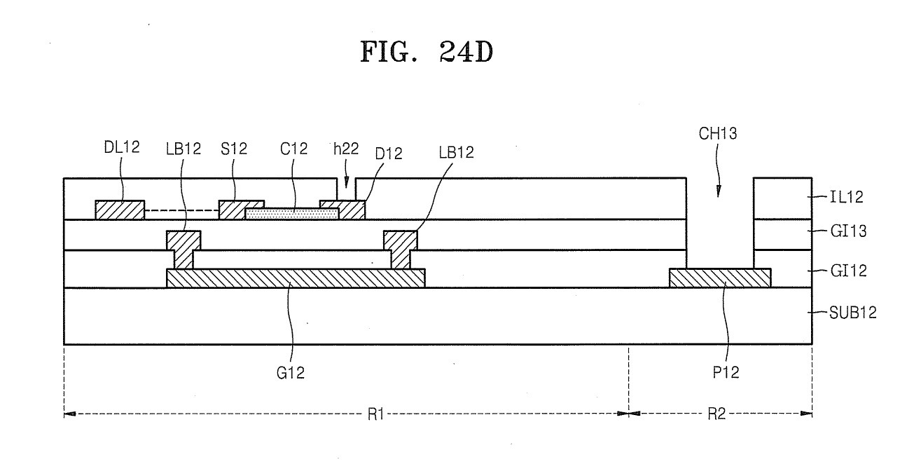

FIGS. 23A through 23F are diagrams showing a part of a method of manufacturing a flat panel display device including a transistor according to example embodiments. The method illustrated in FIGS. 23A through 23F may be used for manufacturing the transistor shown in FIG. 19.

Referring to FIG. 23A, a gate G12 may be formed on a pixel region R1 of a substrate SUB12, and an electrode pad P12 may be formed on a peripheral region R2 of the substrate SUB12. A gate insulation layer GI12 covering the gate G12 and the electrode pad P12 may be formed on the substrate SUB12. A channel layer G12 may be formed on a portion of the gate insulation layer GI12 on the gate G12.

Referring to FIG. 23B, a hole H12 exposing a border portion of the gate G12 may be formed by etching the gate insulation layer GI12. The plane structure of the hole H12 may be similar to that of the light blocking member LB12 shown in FIG. 12.

Referring to FIG. 23C, a light blocking member LB12, which is disposed in the hole H12 and protrudes above the hole H12, may be formed. At the same time, a source electrode S12 and a drain electrode D12, which respectively contact two opposite ends of the channel layer G12, and a data line DL12, which is apart from a side of the light blocking member LB12, may be formed.

Referring to FIG. 23D, an interlayer insulation layer IL12 covering the light blocking member LB12, the channel layer C12, the source electrode S12, the drain electrode D12, and the data line DL12 may be formed on the gate insulation layer GI12.

Referring to FIG. 23E, a hole h20 exposing the data line DL12 and holes h21 and h22 respectively exposing the source electrode S12 and the drain electrode D12 may be formed by etching a portion of the interlayer insulation layer IL12 in the pixel region R1. In the peripheral region R2, a contact hole CH12 exposing the electrode pad P12 may be formed by etching portions of the interlayer insulation layer IL12 and the gate insulation layer GI12.

Referring to FIG. 23F, a contact wiring CW12 interconnecting the data line DL12 and the source electrode S12 may be formed on the interlayer insulation layer IL12, and a pixel electrode PE12 connected to the drain electrode D12 may also be formed. Furthermore, a contact electrode CE12 may be formed in the contact hole CH12 in the peripheral region R2.

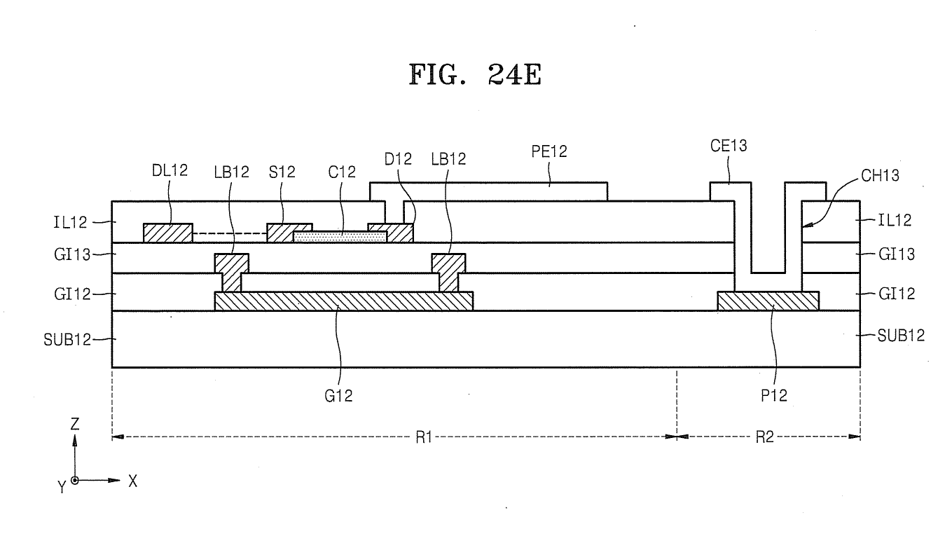

FIGS. 24A through 24E are diagrams showing a part of a method of manufacturing a flat panel display device including a transistor according to example embodiments. The method illustrated in FIGS. 24A through 24E may be used for manufacturing the transistor shown in FIG. 21.

Referring to FIG. 24A, a gate G12 may be formed on a pixel region R1 of the substrate SUB12, and an electrode pad P12 may be formed on a peripheral region R2 of the substrate SUB12. A first gate insulation layer GI12 covering the gate G12 and the electrode pad P12 may be formed on the substrate SUB12. A light blocking member LB12 connected to the gate G12 may be formed in the first gate insulation layer 0112. The plane structure of the light blocking member LB12 may be similar to that of the light blocking member LB12 shown in FIG. 12.

Referring to FIG. 24B, a second gate insulation layer 0113 covering the light blocking member LB12 may be formed on the first gate insulation layer GI12. A channel layer C12 and a source electrode S12 and a drain electrode D12, which respectively contact two opposite ends of the channel layer C12, may be formed on the second gate insulation layer GI13. Furthermore, a data line DL12 connected to the source electrode S12 may be formed. The source electrode S12 may be a portion protruding from the data line DL12.

Referring to FIG. 24C, an interlayer insulation layer IL12 covering the channel layer C12, the source electrode S12, the drain electrode D12, and the data line DL12 may be formed on the second gate insulation layer GI13.

Referring to FIG. 24D, a hole h22 exposing the drain electrode D12 may be formed by etching a portion of the interlayer insulation layer IL12 in the pixel region R1, whereas a contact hole CH13 exposing the electrode pad P12 may be formed by etching portions of the interlayer insulation layer IL12, the second gate insulation layer GI13, and the first gate insulation layer GI12 in the peripheral region R2.

Referring to FIG. 24E, a pixel electrode PE12 connected to the drain electrode D12 may be formed on a portion of the interlayer insulation layer IL12 in the pixel region R1, and a contact electrode CE13 may be formed in the contact hole CH13 in the peripheral region R2.

Methods of forming a bottom substrate of a flat panel display device are described above with reference to FIGS. 23A through 23F and FIGS. 24A through 24E. Since the structure of a top substrate of a flat panel display device and the structure between a top substrate and a bottom substrate of a flat panel display device are well known in the art, detailed description thereof will be omitted.

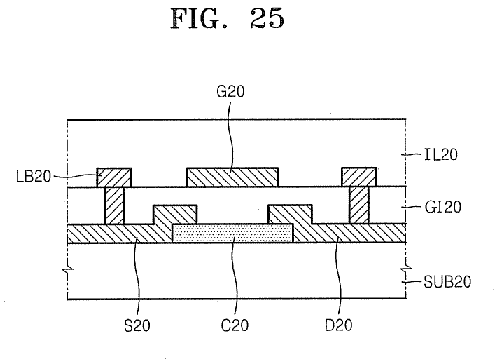

Although example embodiments have been illustrated as including a gate being disposed below a channel layer, example embodiments are not limited thereto. For example, FIG. 25 illustrates an example of a transistor which includes a top gate electrode G20 arranged over a channel layer C20. In FIG. 25, the channel layer C20 is illustrated as being formed on a substrate SUB20, however, example embodiments are not limited thereto as the channel layer C20 may be formed in the substrate SUB20. In FIG. 25, a source electrode S20 and a drain electrode D20 may be provided at different ends of the channel layer C20. In FIG. 25, the gate G20 may be formed on a gate insulating layer GI20 which insulates the gate G20 from the channel layer C20. A light blocking member LB20 may be arranged such that a head of the light blocking member LB20 is also formed on the gate insulating layer GI20. As shown in FIG. 25, the light blocking member LB20 includes a vertical portion extending between the head of the light blocking member LB20 and the source and drain electrodes S20 and D20. The light blocking member LB20 may prevent or reduce light from contacting the channel layer C20.

As in the previous embodiments, the light blocking layer LB20 may be formed completely around the channel layer C20 as in FIG. 12 or substantially around the channel layer C20 as shown in FIGS. 2, 4, 5, 6, 9, and 10 when viewed from above. Although the light blocking member LB20 is illustrated as nearly contacting the source and drain electrodes S20 and D20, example embodiments are not limited thereto as the light blocking layer LB20 may stop short of the source and drain electrodes S20 and D20 or may contact the source and drain electrodes S20 and D20. As shown in FIG. 25, an insulation layer IL20 may be formed on the gate insulating layer GI20 to cover the gate C20 and the light blocking member LB20.

While example embodiments have been particularly shown and described with reference to the figures, it will be understood by one of ordinary skill in the art that various changes in form and details may be made therein without departing from the spirit and scope of the invention as defined by the appended claims. For example, structures of the transistors shown in FIGS. 1 through 6 and 8 through 14 may vary. For example, a transistor according to example embodiments may have a double gate structure, and the channel layers G10, C11, and G12 may have multilayer structures. Furthermore, the methods of manufacturing a transistor shown in FIGS. 15A through 18B may vary. Furthermore, the structure of a flat panel display device and methods of manufacturing the same as described above with reference to FIGS. 19 through 24E may vary. Furthermore, example embodiments may be applied not only to an oxide thin-film transistor (TFT), but also to any of other transistors. Therefore, the scope of the invention is defined not by the detailed description of the invention but by the appended claims, and all differences within the scope will be construed as being included in the present invention.

What is claimed is:

1. A transistor comprising:
a gate on a substrate;
a gate insulation layer on the gate;
a channel layer on the gate insulation layer;
a source electrode and a drain electrode respectively connected to first and second regions of the channel layer; and
a light blocking member surrounding at least a portion of the channel layer, the light blocking member being configured to block laterally incident light.

2. The transistor of claim 1, wherein the light blocking member is in a portion of the gate insulation layer around the channel layer.

3. The transistor of claim 1, wherein the light blocking member is connected to the source and the drain electrodes.

4. The transistor of claim 3, wherein the light blocking member includes
a first member contacting a bottom surface of the source electrode, and
a second member contacting a bottom surface of the drain electrode.

5. The transistor of claim 3, wherein
the source electrode contacts a first end of the channel layer and extends on a portion of the gate insulation layer away from the first end of the channel layer,
the drain electrode contacts a second end of the channel layer and extends on a portion of the gate insulation layer away from the second end of the channel layer, and
the light blocking member includes a first member contacting a bottom surface of the extended portion of the source electrode and a second member contacting a bottom surface of the extended portion of the drain electrode.

6. The transistor of claim 5, wherein
the first member includes a first portion and a second portion, the first portion of the first member extending along the first end of the channel layer and the second portion of the first member extending from an end of the first portion and along another portion of the channel layer, and
the second member comprises a first portion and a second portion, the first portion of the second member extending along the second end of the channel layer and the second portion of the second member extending from an end of the first portion of the second member and along another portion of the channel layer, and
the second portion of the first member and the second portion of the second member are at two opposite sides of the channel layer.

7. The transistor of claim 5, wherein
the first member includes a first portion and a second portion, the first portion of the first member extending along the first end of the channel layer and the second portion of the first member extending from two opposite ends of the first portion of the first member to extend along another portion of the channel layer,
the second member comprises a first portion and a second portion, the first portion of the second member extending along the second end of the channel layer and the second portion of the second member extending from two opposite ends of the first portion of the second member to extend along another portion of the channel layer, and
the second portion of the first member and the second portion of the second member are spaced apart from each other.

8. The transistor of claim 5, wherein the gate extends between the first member and the second member.

9. The transistor of claim 1, wherein the light blocking member is separated from the source electrode and the drain electrode.

10. The transistor of claim 9, wherein a head portion of the light blocking member is at a same level as the source and drain electrodes.

11. The transistor of claim 9, wherein a head portion of the light blocking member is at a different level as compared to the source and drain electrodes.

12. The transistor of claim 9, wherein the light blocking member is separated from the gate.

13. The transistor of claim 9, wherein the light blocking member is connected to the gate.

14. The transistor of claim 1, further comprising:
an interlayer insulation layer on the gate insulation layer, the interlayer insulation layer covering the channel layer,
wherein the light blocking member is in the interlayer insulation layer and the gate insulation layer.

15. The transistor of claim 14, wherein the light blocking member protrudes above the interlayer insulation layer.

16. The transistor of claim 14, further comprising:
a first plug connecting the source electrode to the channel layer; and
a second plug connecting the drain electrode to the channel layer, wherein the source electrode and the drain electrode are on the interlayer insulation layer, and the first plug and the second plug are in the interlayer insulation layer.

17. The transistor of claim 14, wherein the light blocking member is separated from the source and drain electrodes.

18. The transistor of claim 14, wherein the light blocking member includes a first member and a second member that are separated from each other,
the first member includes a first portion and a second portion, the first portion of the first member extending along a first end of the channel layer and the second portion of the first member extending along another portion of the channel layer,
the second member includes a first portion and a second portion, the first portion of the second member extending along a second end of the channel layer and the second portion of the second member extending along another portion of the channel layer, and
the second portion of the first member and the second portion of the second member are at two opposite sides of the channel layer.

19. The transistor of claim 18, wherein at least one of the source and drain electrodes extends between the first member and the second member.

20. The transistor of claim 18, wherein the gate extends between the first member and the second member.

21. The transistor of claim 1, wherein the light blocking member completely surrounds the channel layer.

22. The transistor of claim 21, wherein the light blocking member contacts the gate and is separated from the source and drain electrodes.

23. The transistor of claim 21, wherein
the gate has a greater width than the channel layer; and
the light blocking member contacts a border of the gate.

24. The transistor of claim 21, further comprising:
a second gate insulation layer on the gate insulation layer, the second gate insulation layer covering the light blocking member, wherein the channel layer and the source and drain electrodes are on the second gate insulation layer.

25. The transistor of claim 1, wherein the channel layer comprises an oxide semiconductor.

26. The transistor of claim 1, wherein the channel layer comprises a non-oxide semiconductor.

27. The transistor of claim 1, wherein the gate includes an opaque material.

28. A flat panel display device comprising:
the transistor of claim 1.

29. The flat panel display device of claim 28, wherein the transistor is configured to act as one of a switching device and a driving device.

30. The flat panel display device of claim 28, wherein the transistor is arranged in a pixel region of the flat panel display device.

31. The flat panel display device of claim 30, further comprising:
an electrode pad on the substrate and a contact electrode connected to the electrode pad.

32. The flat panel display device of claim 30, further comprising:
a contact wiring connecting the source electrode to a dataline; and
a pixel electrode connected to the drain electrode.

33. The flat panel display device of claim 32, further comprising:
an interlayer insulation layer on the gate insulation layer, wherein the contact wiring and the pixel electrode are on the interlayer insulation layer.

34. The flat panel display device of claim 30, further comprising:
a second gate insulation layer on the gate insulation layer;
an interlayer insulation layer on the second gate insulation layer;
a pixel electrode on the interlayer insulation layer; and
a dataline on the second gate insulation layer, wherein the pixel electrode is connected to the drain electrode via a plug and the dataline is connected to the source electrode.

35. The flat panel display device of claim 34, wherein the dataline, the source electrode, and the drain electrode are on the second gate insulation layer.

36. The flat panel display device of claim 35, wherein the light blocking member is on the gate insulation layer.

37. The flat panel display device of claim 36, wherein the gate and the light blocking member are connected via a plug.

38. The flat panel display device of claim 37, further comprising:
an electrode pad on the substrate.

39. The flat panel display device of claim 38, further comprising:
a contact electrode passing through the gate insulation layer, the second gate insulation layer, and the interlayer insulation layer.
